(19) United States
(12) Patent Application Publication
(10) Pub. No.: US 2016/0352322 A1
(43) Pub. Date: Dec. 1, 2016

(54) DIGITAL PULSE WIDTH MODULATION CONTROL FOR LOAD SWITCH CIRCUITS

(71) Applicant: HEWLETT-PACKARD DEVELOPMENT COMPANY, L.P., Houston, TX (US)

(72) Inventors: Robert S Wright, Spring, TX (US); Michael R. Durham, Tomball, TX (US); Nam Nguyen, Houston, TX (US)

(21) Appl. No.: 14/908,722

(22) PCT Filed: Jul. 31, 2013
(86) PCT No.: PCT/US2013/052949

§ 371 Date: Jan. 29, 2016

(51) Int. Cl. H03K 17/0814; H02M 3/156; H02M 1/32; H03K 7/08

(52) U.S. Cl. CPC H03K 17/08142; H03K 7/08; H02M 3/156; H02M 1/32

(57) ABSTRACT

Example implementations relate to controlling a field-effect transistor (FET) switch in a load switch circuit. A digital pulse width modulated (PWM) voltage signal may be applied to a gate of a FET switch. The pulse width of the PWM voltage signal may be set to a first value. The pulse width of the digital PWM voltage signal may be digitally incremented to a second value. The digital PWM voltage signal having the pulse width of the second value may be applied to the gate of the FET switch.

### BACKGROUND

Switches may be used to disconnect and reconnect supplies to their respective loads. Soft start switches may be used when connecting power supplies to loads to prevent sudden voltage dips in the power supplies and to prevent damage to elements connected to the power supplies. Slow soft start times may be used to achieve high load current connections and high load capacitance connections.

### BRIEF DESCRIPTION OF THE DRAWINGS

The following retailed description references the drawings, wherein:

FIG. 1 is a schematic diagram of an example system having a switch coupled to a digitally controlled driver;

FIG. 2 is a schematic diagram of an example load switch circuit having a digitally controlled driver coupled to a soft start switch;

FIG. 3A is a schematic diagram of an example field-effect transistor (FET) load switch circuit having a digitally controlled driver;

FIG. 3B is a schematic diagram of an example FET load switch circuit having a digitally controlled driver coupled to a super input/output (I/O) chip;

FIG. 4 is a flowchart of an example method for controlling a FET switch in a load switch circuit; and

FIG. 5 is a flowchart of an example method for controlling the pulse width of a pulse width modulated (PWM) voltage signal.

### DETAILED DESCRIPTION

Soft start switches may be used with power supplies that are frequently disconnected and reconnected to their respective loads. Field-effect transistor (FET) switches may be used to soft-start loads. A slow soft start achieved by a linear gate drive on a FET switch may leave the FET vulnerable to a safe operating area (SOA) violation, and may also waste power because the FET may have a large drain-source resistance when operating in linear (triode) mode. In addition, damage to the FET may occur during fault conditions, such as large capacitances and short-circuits of loads.

Pulse width modulated (PWM) voltage signals may be applied to gates of FET switches to achieve soft starts. Existing load switch circuits may use analog PWM voltage signals, for example using a FET and resistor to charge and discharge a capacitor at the gate of the FET switch. The resistor and/or capacitor values may need to be changed whenever a different soft start time is desired.

The present disclosure addresses at least these issues by providing for digital PWM voltage signals that may be digitally modified to achieve desired soft start times. The duty cycle of digital PWM voltage signals in the present disclosure may be swept from essentially zero percent to essentially one hundred percent at varying rates to achieve high fault tolerance and accommodate different load conditions. Throughout the present disclosure, it should be understood that a quantity that is “essentially” a specified value means a quantity that is within one percent of the specified value, or a quantity that is indistinguishable from the specified value in the context of a circuit of the present disclosure. Digital PWM voltage signals may allow slow soft start times to be achieved without operating FET switches in linear mode, and may allow soft start times to be varied without changes in hardware (e.g., resistance/capacitance values). Digital PWM voltage signals may be easily and cheaply converted back to analog signals, which may save costs while retaining the advantage of allowing soft start times to be changed without changes in hardware.

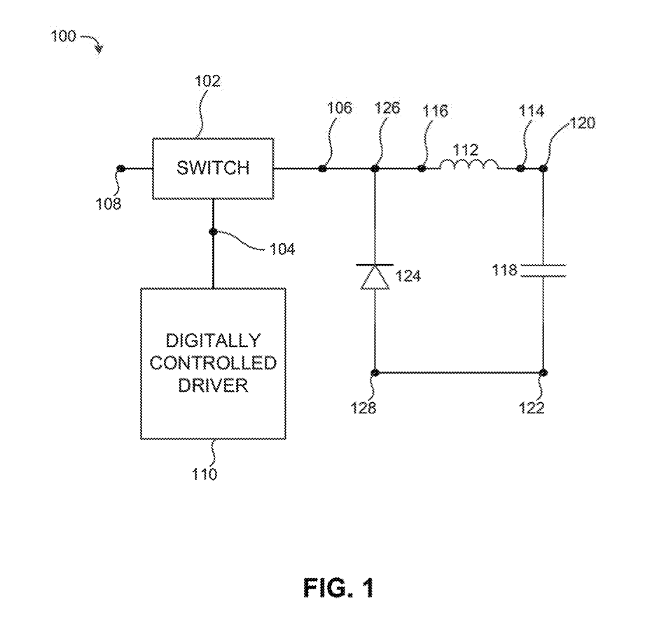

Referring now to the drawings, FIG. 1 is a schematic diagram of an example system 100 having a switch coupled to a digitally controlled driver. System 100 includes a switch 102 having a terminal 104 coupled to digitally controlled driver 110. Driver 110 may be an integrated circuit (IC), or may be made up of discrete components. Driver 110 may output a voltage signal, which may be applied at terminal 104.

The voltage signal output by driver 110 may alternate between a first value and a second value. Current may be allowed to flow between terminal 106 and terminal 108 of switch 102 (i.e., switch 102 may act as a closed switch between terminals 106 and 108) when the voltage signal applied at terminal 104 is at the first value. Current flow between terminal 106 and terminal 108 of switch 102 may be essentially zero (i.e., switch 102 may act as an open switch between terminals 106 and 108) when the voltage signal applied at terminal 104 is at the second value. Switch 102 may include a bipolar junction transistor (BJT) an insulated gate bipolar transistor (IGBT), or a field-effect transistor (FET), such as a metal-oxide-semiconductor field-effect transistor (MOSFET), junction field-effect transistor (JFET), or metal-semiconductor field-effect transistor (MESFET), or any suitable switching device. Terminal 104 may be a gate terminal of a FET; terminal 106 and terminal 108 may be source/drain terminals.

For example, switch 102 may be an n-channel MOSFET (NMOS) with terminal 104 being the gate, terminal 106 being the source, and terminal 108 being the drain. The first value of the voltage signal output by driver 110 may be a value that causes the voltage between the gate and source of the NMOS to equal or exceed the threshold voltage, allowing current to flow between the drain and source. The second value of the voltage signal output by driver 110 may be a value that causes the voltage between the gate and source of the NMOS to be below the threshold voltage, so the drain-source current may be essentially zero.

The voltage signal output by driver 110 may be a digital pulse width modulated (PWM) voltage signal. The pulse width of the PWM voltage signal may be digitally controlled. As used herein, the term “pulse width” refers to the amount of time, within a period of a signal (e.g., a digital PWM voltage signal), that the value of the signal is above or below a reference value (e.g. electrical ground). Driver 110 may by digitally programmed (e.g., by loading digital instructions stored in registers into a processor in driver 110) to increase the duty cycle of the PWM voltage signal over time. The increase in duty cycle may be implemented by digitally incrementing the pulse width of the PWM voltage signal over time. For example, the duty cycle of the PWM voltage signal may be swept from essentially zero percent to essentially one hundred percent over a period of time (e.g., three milliseconds, ten milliseconds) by digitally increasing the pulse width of the PWM voltage signal by a certain amount at predetermined intervals of time (e.g., every tenth of a millisecond). It should be understood that the time intervals between increases in the pulse width may not be equal in length, and that the amount by which the pulse width is increased may not be the same every time an increase in pulse width occurs. Driver 110 may be digitally programmed with the rate at which the pulse width is increased, as well with the amount of each increase in pulse width.

System 100 may also include inductor 112, capacitive element 118, and diode 124. Terminal 114 of inductor 112 may be coupled to terminal 120 of capacitive element 118. Capacitive element 118 may include a load capacitance. Terminal 116 of inductor 112 may be coupled to cathode terminal 126 of diode 124 and to terminal 106 of switch 102. Anode terminal 128 of diode 124 may be coupled to terminal 122 of capacitive element 118. Anode terminal 128 of diode 124 and terminal 122 of capacitive element 118 may be connected to an electrical ground.

System 100 may be used as a load switch circuit to connect a voltage source (e.g., power rail), which may be coupled to terminal 108, to a load, which may be coupled in parallel with capacitive element 118. By driving terminal 104 of switch 102 with a PWM voltage signal and sweeping the duty cycle of the PWM voltage signal from essentially zero percent to essentially one hundred percent, switch 102 may gradually transition from being open all the time (i.e., when the duty cycle of the PWM voltage signal is essentially zero percent) to being closed all the time (e.g., when the duty cycle of the PWM voltage signal is essentially one hundred percent). System 100 may thus provide a soft start for a load that is being connected to its power supply. Soft-starting the load may allow current that is being delivered to the load to build up slowly, protecting the upstream power supply, and other components connected to the power supply, from sudden dips in voltage.

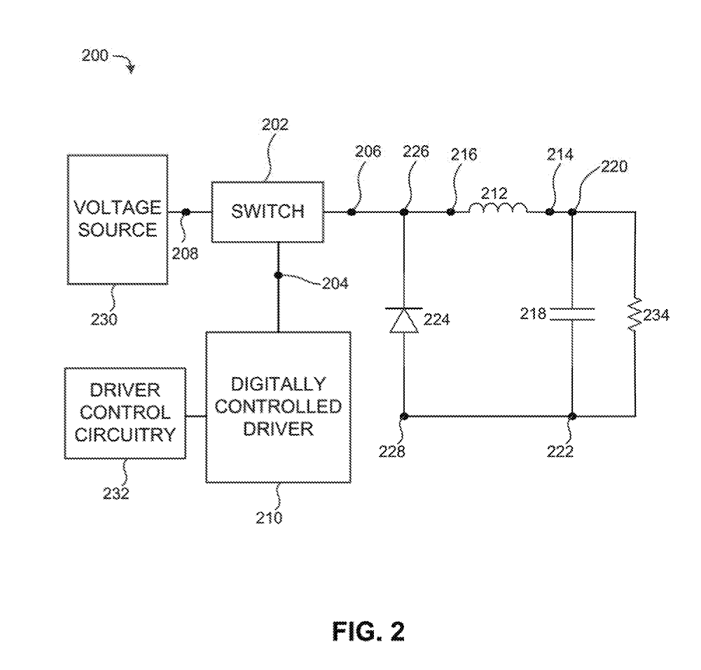

FIG. 2 is a schematic diagram of an example load switch circuit 200 having a digitally controlled driver coupled to a soft start switch. Switch 202 of circuit 200 may be analogous to (e.g., have functions and/or components similar to) switch 102 of system 100. Terminals 204, 206, and 208 of switch 202 may be analogous to terminals 104, 106, and 108, respectively, of switch 102. Digitally controlled driver 210 may be coupled to terminal 204 of switch 202. Driver 210 of circuit 200 may output a voltage signal, such as a digital PWM voltage signal, and may be analogous to driver 110 of system 100.

Inductor 212 of circuit 200 may be analogous to inductor 112 of system 100; terminal 214 and terminal 216 of inductor 212 of circuit 200 may be analogous to terminal 114 and terminal 116, respectively, of inductor 112 of system 100. Capacitive element 218 of circuit 200 may be analogous to capacitive element 118 of system 100; terminal 220 and terminal of capacitive element 218 of circuit 200 may be analogous to terminal 120 and terminal 122, respectively, of capacitive element 118 of system 100. Diode 224 of circuit 200 may be analogous to diode 124 of system 100; cathode terminal 226 and anode terminal 228 of diode 224 of circuit 200 may be analogous to cathode terminal 126 and anode terminal 128, respectively, of diode 124 of system 100. Anode terminal 228 of diode 224 and terminal 222 of capacitive element 218 may be connected to an electrical ground.

In circuit 200, resistive load 234 may be coupled to terminal 214 of inductor 212 and in parallel with capacitive element 218. Resistive load 234 may draw current from voltage source 230, which may be coupled to terminal 208 of switch 202. Voltage source 230 may include a power rail, such as a DC power rail of an electronic device (e.g., notebook computer, desktop computer, workstation, tablet computing device, mobile phone, electronic book reader, gaming device, and/or retail point of sale device). Resistive load 234 may include a component that may be frequently disconnected and reconnected to voltage source 230, for example for power-saving purposes. For example, resistive load 234 may include a display component of a notebook computer that is disconnected from a power rail of the notebook computer when the notebook computer is put into “sleep” mode. The display component may be reconnected to the power rail during normal operation of the notebook computer.

Driver control circuitry 232 may be coupled to digitally controlled driver 210 in circuit 200. Driver control circuitry 232 may transmit digital commands to driver 210 to control the pulse width of a digital PWM voltage signal that is output by driver 210. For example, driver control circuitry 232 may instruct driver 210 to digitally increment the pulse width of a PWM voltage signal over a period of time. During the period of time, the duty cycle of the PWM voltage signal may be increased from essentially zero percent to essentially one hundred percent. Driver control circuitry 232 may control the rate at which the pulse width is increased, as well as the amount of each increase in pulse width. Driver control circuitry 232 may set the pulse width of the PWM voltage signal based on an operating frequency of resistive load 234 (e.g., shorter pulse widths may be selected for resistive loads with higher operating frequencies).

Driver control circuitry 232 may include digital control logic for increasing the pulse width of a PWM voltage signal over time. Driver control circuitry may include or may be coupled to a plurality of registers, which may store a bit pattern for increasing the pulse width. For example, a logical ‘1’ may represent an increase in the pulse width, and a logical ‘0’ may represent keeping the pulse width the same. Contents of the registers may be loaded into driver 210, which may read the bit pattern and output a digital PWM voltage signal accordingly.

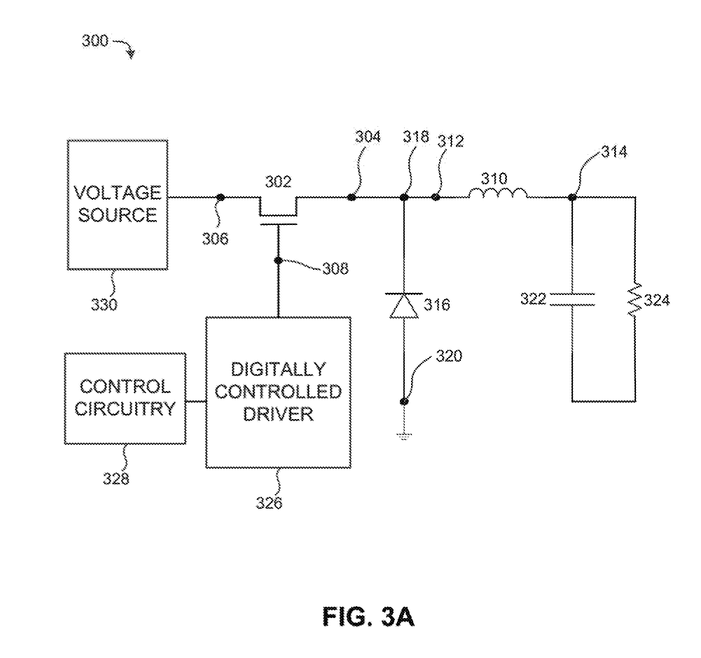

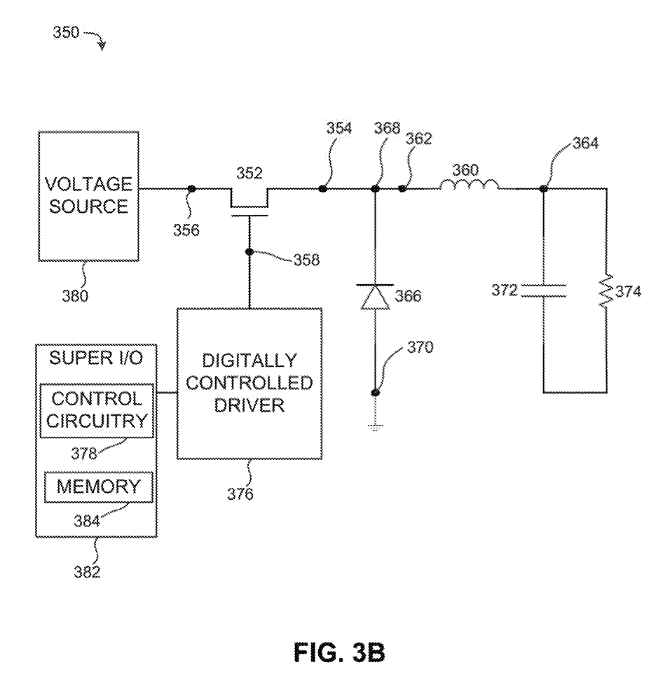

FIG. 3A is a schematic diagram of an example FET load switch circuit 300 having a digitally controlled driver. FET switch 302 of circuit 300 may be a metal-oxide-semiconductor field-effect transistor (MOSFET), junction field-effect transistor (JFET), metal-semiconductor field-effect transistor (MESFET), or any other FET suitable for use in a load switch circuit. It should be understood that discussions in the present disclosure regarding FET switches may also be applicable other types of switches, such as BJT switches or IGBT switches. Terminal 308 of FET switch 302 may be a gate terminal; terminal 304 and terminal 306 may be source/drain terminals. For example, in implementations where FET switch 302 is an NMOS, terminal 308 may be the gate terminal, terminal 304 may be the source terminal, and terminal 306 may be the drain terminal. In implementations where FET switch 302 is a p-channel MOSFET (PMOS), terminal 308 may be the gate terminal, terminal 304 may be the drain terminal, and terminal 306 may be the source terminal.

Terminal 304 of FET switch 302 may be coupled to cathode terminal 318 of diode 316 and to terminal 312 of inductor 310. Anode terminal 320 of diode 316 may be connected to an electrical ground. Terminal 314 of inductor 310 may be coupled to capacitive element 322, which may include a capacitive load. Resistive load 324 may be coupled in parallel to capacitive element 322. The terminal of capacitive element 322 that is not coupled to inductor 310 may be connected to an electrical ground. Inductor 310, diode 316, capacitive element 322, and resistive load 324 may be analogous to inductor 212, diode 224 capacitive element 218, and resistive load 234, respectively, of circuit 200.

Voltage source 330 may be coupled to terminal 306 of FET switch 302. Voltage source 330 of circuit 300 may be analogous to voltage source 230 of circuit 200, and may provide power to resistive load 324. Terminal 308 of FET switch 302 may be coupled to digitally controlled driver 326, which may be analogous to driver 210 of circuit 200. Driver 326 may output a digital PWM voltage signal that may be applied to the gate of FET switch 302. Control circuitry 328 may be coupled to driver 326 and may transmit digital commands to driver 326 to digitally increment a pulse width of a digital PWM voltage signal that is output by driver 326. In some implementations, control circuitry 328 may be on a super input/output (I/O) chip coupled to driver 326, as discussed further with respect to FIG. 3B.

Control circuitry 328 may digitally instruct driver 326 to increment the pulse width of a PWM voltage signal over a period of time such that the duty cycle of the PWM voltage signal is increased from essentially zero percent to essentially one hundred percent during the period of time. For example, control circuitry 328 may transmit a bit string to driver 326. When driver 326 reads bits of a first value (e.g., logical ‘1’) in the bit string, driver 326 may increase the pulse width, and when driver 326 reads bits of a second value (e.g., logical ‘0’), driver 326 may keep the pulse width the same. Control circuitry 328 may transmit multi-bit instructions to driver 326 to increment the pulse width by various amounts, and/or to decrement the pulse width by various amounts. Control circuitry 328 may digitally control the rate at which the pulse width is increased, as well as the amount of each increase in pulse width. Control circuitry 328 may set the pulse width of the PWM voltage signal based on an operating frequency of resistive load 324 (e.g., shorter pulse widths may be selected for resistive loads with higher operating frequencies).

The PWM voltage signal that is output by driver 326 may alternate between a first value and a second value. When the PWM voltage signal is at the first value, FET switch 302 may act as a closed switch between terminals 306 and 304, connecting voltage source 330 to terminal 312 of inductor 310 and to cathode terminal 318 of diode 316, and providing a path for current to flow from voltage source 330 to resistive load 324. When the PWM voltage signal is at the second value, FET switch 302 may act as an open switch between terminals 306 and 304, and current flow between terminals 306 and 304 may be essentially zero. Diode 316 may function as a catch rectifier to (temporarily) keep current flowing through resistive load 324 when FET switch 302 acts as an open switch.

The first value of the PWM voltage signal may be a value that causes FET switch 302 to operate in saturation mode, and the second value may be a value that causes FET switch 302 to operate in cutoff mode. Such operation of a FET in either saturation or cutoff mode may minimize power dissipation (e.g., calculated by multiplying current squared and resistance) by FET switch 302 because the resistance across terminals 306 and 304 may be very low when FET switch 302 operates in saturation mode, and virtually no current may flow between terminals 306 and 304 when FET switch 302 operates in cutoff mode. In addition, avoiding linear mode operation of FET switch 302 may prevent violations of the safe operating area (SOA) of the FET.

By gradually increasing the pulse width of the PWM voltage signal (e.g., increasing the amount of time the PWM voltage signal is at the first value), current flowing through resistive load 324 may be built up slowly. In implementations where resistive load 324 may draw very high currents, diode 316 may be replaced by a FET. In such implementations, driver 326 may include a synchronous controller (e.g., synchronous rectifier driver IC), which may be used to drive both FET switch 302 and the FET used in place of diode 316.

FIG. 3B is a schematic diagram of an example FET load switch circuit 350 having a digitally controlled driver coupled to a super I/O chip. FET switch 352 of circuit 350 may be analogous to FET switch 302 of circuit 300. Terminals 354, 356, and 358 of FET switch 352 may be analogous to terminals 304, 306, and 308, respectively, of FET switch 302. Digitally controlled driver 376 may be coupled to terminal 358 of FET switch 352. Driver 376 of circuit 350 may output a voltage signal, such as a digital PWM voltage signal, and may be analogous to driver 326 of circuit 300.

Inductor 360 of circuit 350 may be analogous to inductor 310 of circuit 300; terminal 362 and terminal 364 of inductor 360 of circuit 350 may be analogous to terminal 312 and terminal 314, respectively, of inductor 310 of circuit 300. Capacitive element 372 of circuit 350 may be analogous to capacitive element 322 of circuit 300. Diode 366 of circuit 350 may be analogous to diode 316 of circuit 300; cathode terminal 368 and anode terminal 370 of diode 366 of circuit 350 may be analogous to cathode terminal 318 and anode terminal 320, respectively, of diode 316 of circuit 300. Anode terminal 370 of diode 366 and the terminal of capacitive element 372 that is not connected to inductor 360 may be connected to an electrical around. Resistive load 374 of circuit 350 may be analogous to resistive load 324 of circuit 300. Voltage source 380 may be coupled to terminal 356 of FET switch 352, and may provide power to resistive load 374. Voltage source 380 of circuit 350 may be analogous to voltage source 330 of circuit 300.

Driver 376 of circuit 360 may be coupled to super I/O chip 382. Super I/O chip 382 may include a memory 384. Memory 384 may store instructions regarding a rate at which to increment the pulse width of a PWM voltage signal. For example, memory 384 may store a pattern for is the pulse width of a digital PWM voltage signal. The pattern may be an increase in the pulse width by a certain amount at regular time intervals, or the pulse width may increase by different amounts at time intervals of varying lengths. Memory 384 may initially be programmed with a default pattern. Additional patterns may be stored in memory 384, or memory 384 may be reprogrammed with a different pattern. Different patterns may be used depending on the desired rate of increase in pulse width (which may be related to the desired rate of increase in duty cycle) of a digital PWM voltage signal applied to terminal 358 of FET switch 352. Memory 384 may include registers that are programmed with a bit pattern corresponding to the desired pattern.

Super I/O chip 382 may include control circuitry 378. Control circuitry 378 may select a pattern from memory 384 based on an operating frequency of resistive load 374 and/or based on a desired rate of increase of the pulse width or duty cycle of a digital PWM voltage signal. Control circuitry 378 may generate digital commands (e.g., based on a selected pattern) for digitally incrementing a pulse width of a digital PWM voltage signal that is output by driver 376. Super I/O chip 382 may have a pin that is connected to driver 376 and that may be used to transmit digital commands to driver 376.

Super I/O chip 382 may detect faults and/or other conditions that may adversely affect FET switch 352 and/or voltage source 380. The term “fault” as used herein refers to an abnormal electric current in a circuit, or a situation that causes abnormal or unexpected behavior of a circuit component. It should be understood that the term “adversely affect”, as used herein with respect to a fault or condition, refers to a condition that may damage a circuit component and/or cause a component to operate outside of safe or specified operating conditions. Super I/O chip 382 may cause actions to be performed that protect FET switch 352 and/or voltage source 380. For example, super I/O chip 382 may detect that resistive load 374 has been short-circuited, which may cause more current to flow through FET switch 352 and cause the FET to malfunction. A short-circuit of resistive load 374, or of another load connected to voltage source 380, may pull down the output voltage of voltage source 380, which may cause the output voltage to dip out of specified operating conditions and damage voltage source 380 and/or other components. Super I/O chip 382 may detect such conditions, and in response may cause FET switch 352 to act as an open switch in order to protect the FET and/or voltage source 380. For example, control circuitry 378 of super I/O chip 382 may digitally set the pulse width of a PWM voltage signal that is output by driver 376 such that the PWM voltage signal has a duty cycle of essentially zero percent, causing FET switch 352 to act as an open switch (i.e., open circuit) between terminals 354 and 356. Causing FET switch 352 to act as an open switch may isolate voltage source 380 from a short-circuit of resistive load 374 and prevent a current overload of the FET.

Super I/O chip 382 may be connected to elements other than elements shown in FIG. 3B. Super I/O chip 382 may receive information from voltage feedback loops and current feedback loops involving elements not shown in FIG. 3B (e.g., other loads connected to voltage source 380), but that may affect operation of the elements shown in FIG. 3B.

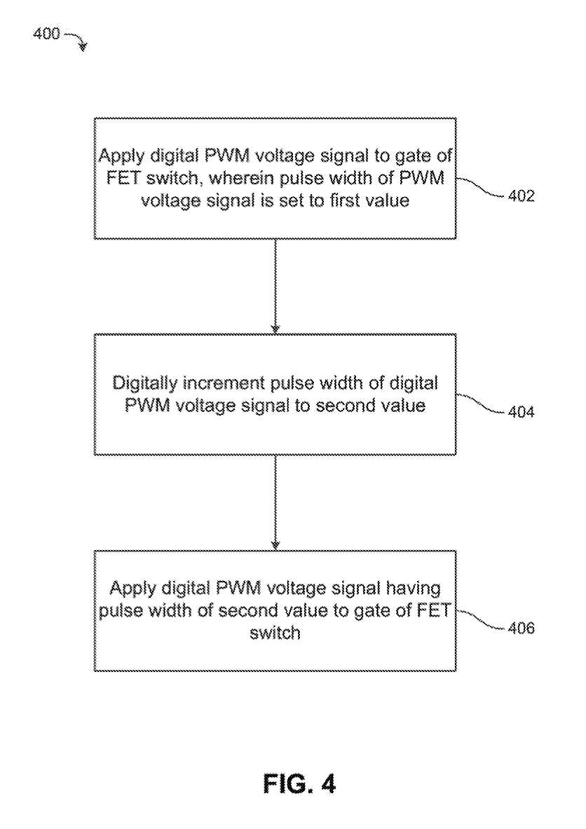

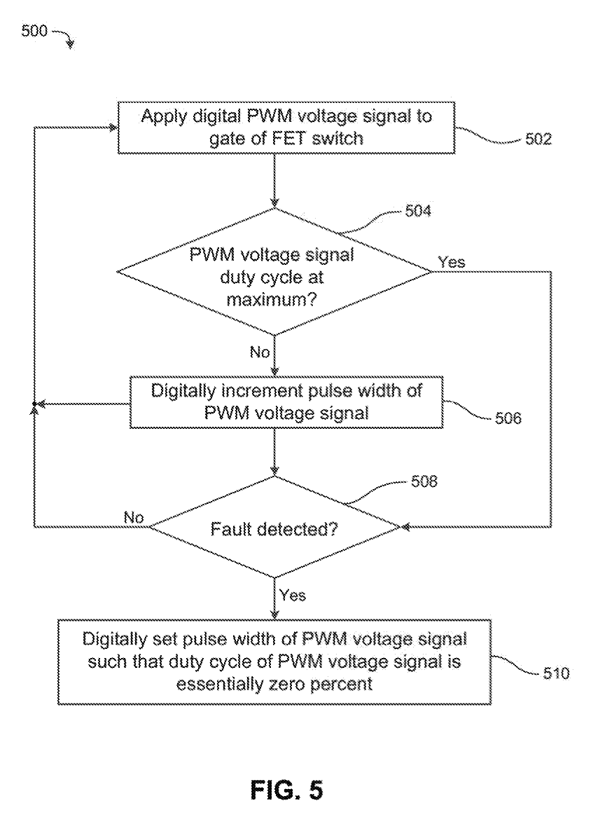

Methods related to PWM voltage signals applied at gates of FET switches are discussed with respect to FIGS. 4-5. FIG. 4 is a flowchart of an example method 400 for controlling a FET switch in a load switch circuit. Although execution of method 400 is described below with reference to circuit 300 of FIG. 3A, it should be understood that execution of method 400 may be pert ted by other suitable systems, such a system 100, circuit 200, or circuit 350. Method 400 may be implemented in the form of executable instructions stored on a machine-readable storage medium, and/or in the form of electronic circuitry.

Method 400 may start in block 402, where circuit 300 may apply a digital PWM voltage signal to a gate of a FET switch. The pulse width of the digital PWM voltage signal may be set to a first value, and may be related to the duty cycle of the PWM voltage signal. For example, the first value may be essentially zero, which may correspond to the duty cycle of the PWM voltage signal being essentially zero percent. A first terminal of the FET switch may be coupled to a first terminal of an inductor and to a cathode of a diode. A load may be coupled to a second terminal of the inductor. A second terminal of the FET switch may be coupled to a voltage source.

Next, in block 404, circuit 300 may digitally increment a pulse width of the digital PWM voltage signal to a second value. The second value may be a positive non-zero value; a PWM voltage signal having a pulse width of the second value may have a duty cycle between zero percent and one hundred percent. Circuit 300 may determine the first value and the second value of the pulse width of the PWM voltage signal based on an operating frequency of the load.

Finally, in block 406, circuit 300 may apply a digital PWM voltage signal having a pulse width of the second value to the gate of the FET switch. It should be understood that circuit 300 may continue to digitally increment the pulse width of the PWM voltage signal over a time period such that a duty cycle of the PWM voltage signal increases from essentially zero percent to essentially one hundred percent during the time period.

FIG. 5 is a flowchart of an example method 500 for controlling the pulse width of a pulse width modulated (PWM) voltage signal. Although execution of method 500 is described below with reference to circuit 300 of FIG. 3A, it should be understood that execution of method 500 may be performed by other suitable systems, such as system 100, circuit 200, or circuit 350. Method 500 may be implemented in the form of executable instructions stored on a machine-readable storage medium, and/or in the form of electronic circuitry.

Method 500 may start in block 502, where circuit 300 may apply a digital PWM voltage signal to a gate of a FET switch. The FET switch, when closed, may provide a current path from a voltage source to a resistive load.

Next, in block 504, circuit 300 may determine whether the duty cycle of the PWM voltage signal is at a maximum value. The maximum value may be one hundred percent, or may be another predetermined value.

When circuit 300 determines that the duty cycle of the PWM voltage signal is not at a maximum value, method 500 may proceed to block 506, in which circuit 300 may digitally increment the pulse width of the PWM voltage signal. Method 500 may then loop back to block 502.

When circuit 300 determines that the duty cycle of the PWM voltage signal is at a maximum value, method 500 may proceed to block 508, in which circuit 300 may determine whether a fault has been detected. A fault may be a condition that may adversely affect the voltage source and/or or the FET switch. It should be understood that a determination of whether a fault has been detected may be made before the duty cycle of the PWM voltage signal reaches the maximum value.

When circuit 300 determines that a fault has not been detected, method 500 may loop back to block 502. When circuit 300 determines that a fault has been detected, method 500 may proceed to block 510, in which circuit 300 may digitally set the pulse width of the PWM voltage signal such that the duty cycle of the PWM voltage signal is essentially zero percent. Setting the duty cycle of the PWM voltage signal to essentially zero percent may cause the FET switch to act as an open switch, which may prevent damage to the FET switch and/or voltage source.

The foregoing disclosure describes control of digital PWM voltage signals for FET switches in load switch circuits. Example implementations described herein enable high fault tolerance and flexibility in accommodating load conditions while saving power and cost.

We claim:

1. A system for controlling a switch, the system comprising:
a digitally controlled driver, coupled to a first terminal of the switch, to output a digital pulse width modulated (PWM) voltage signal, wherein:
current is allowed to flow between a second terminal of the switch and a third terminal of the switch when the PWM voltage signal is at a first value;
current flow between the second and third terminals of the switch is essentially zero when the PWM voltage signal is at a second value; and
pulse width of the PWM voltage signal is digitally controlled;
an inductor having a first terminal coupled to a first terminal of a capacitive element, and a second terminal coupled to the second terminal of the switch; and
a diode having a cathode coupled to the second terminal of the switch, and an anode coupled to a second terminal of the capacitive element.

2. The system of claim 1, wherein:
the switch is a field-effect transistor (FET); and
the first terminal of the switch is a gate of the FET.

3. The system of claim 1, wherein:
a voltage source is coupled to the second terminal of the switch; and
a resistive load is coupled to the first terminal of the inductor and in parallel with the capacitive element.

4. The system of claim 3, wherein the pulse width of the PWM voltage signal is set based on an operating frequency of the resistive load.

5. The system of claim 1, further comprising driver control circuitry to transmit digital commands to the driver to control the pulse width of the PWM voltage signal.

6. The system of claim 1, wherein the pulse width of the PWM voltage Signal is digitally incremented over a time period such that a duty cycle of the PWM voltage signal increases from essentially zero percent to essentially one hundred percent during the time period.

7. A field-effect transistor load switch circuit comprising:
a field-effect transistor (FET) switch having a first terminal coupled to a first terminal of an inductor and to a cathode of a diode, wherein:
a second terminal of the FET switch is coupled to a voltage source; and
a capacitive load and a resistive load are coupled in parallel to a second terminal of the inductor;
a digitally controlled driver, coupled to a gate of the FET switch, to output a digital pulse width modulated (PWM) voltage signal applied to the gate of the FET switch; and
control circuitry coupled to the driver to digitally increment a pulse width of the PWM voltage signal over time.

8. The circuit of claim 7, wherein the control circuitry is on a super input/output (I/O) chip coupled to the driver.

9. The circuit of claim 8, wherein the super I/O chip comprises a memory to store instructions regarding a rate at which to increment the pulse width of the PWM voltage signal.

10. The circuit of claim 7, wherein:
the PWM voltage signal alternates between a first value and a second value;
the FET switch acts as a closed switch, connecting the voltage source to the first terminal of the inductor and to the cathode of the diode, when the PWM voltage signal is at the first value; and
the FET switch acts as an open switch when the PWM voltage signal is at the second value.

11. A method controlling field-effect transistor (FET) switch, the method comprising:
applying a digital pulse width modulated (PWM) voltage signal to a gate of the FET switch, wherein a pulse width of the digital PWM voltage signal is set to a first value;
digitally incrementing the pulse width of the digital PWM voltage signal to a second value; and
applying the digital PWM voltage signal having the pulse width of the second value to the gate of the FET switch.

12. The method of claim 11, further comprising digitally incrementing the pulse width of the PWM voltage signal over a time period such that a duty cycle of the PWM voltage signal increases from essentially zero percent to essentially one hundred percent during the time period.

13. The method of claim 11, wherein:
a first terminal of the FET switch is coupled to a first terminal of an inductor and cathode of a diode; and
a second terminal of the FET switch is coupled to a voltage source.

14. The method of claim 13, wherein a load is coupled to a second terminal of the inductor, the method further comprising determining the first value and the second value of the pulse width of the PWM voltage signal based on an operating frequency of the load.

15. The method of claim 11, further comprising:
detecting a fault that adversely affects the FET switch; and
digitally setting the pulse width of the PWM voltage signal such that PWM voltage signal has a duty cycle of essentially zero percent.
